(19) United States
(12) Patent Application Publication
(10) Pub. No.: US 2026/0090277 A1
(43) Pub. Date: Mar. 26, 2026

(54) MAGNETORESISTIVE RANDOM-ACCESS MEMORY DEVICE WITH DIVIDED TUNNEL BARRIER

(71) Applicant: International Business Machines Corporation, Armonk, NY (US)

(72) Inventors: Oscar van der Straten, Guilderland Center, NY (US); Praneet Adusumilli, Somerset, NJ (US); Chih-Chao Yang, Glenmont, NY (US)

(21) Appl. No.: 18/895,739

(22) Filed: Sep. 25, 2024

(51) Int. Cl. H10N 50/01; H10B 61/00; H10N 50/10; H10N 50/80

(52) U.S. Cl. CPC H10N 50/01; H10B 61/00; H10N 50/10; H10N 50/80

(57) ABSTRACT

A magnetic tunnel junction device and formation thereof. The magnetic tunnel junction device includes a magnetic tunnel junction pillar formed above a bottom electrode. The magnetic tunnel junction pillar includes a reference layer formed above the bottom electrode, a free layer formed above the reference layer, and a tunnel barrier separating the reference layer from the free layer. The tunnel barrier includes a first tunnel barrier layer formed along top and sidewall surfaces of the reference layer, and a second tunnel barrier layer formed along bottom and sidewall surfaces of the free layer. The magnetic tunnel junction device further includes a top electrode formed above the magnetic tunnel junction pillar.

### BACKGROUND

The present invention generally relates to fabrication methods and structures for magnetic tunnel junction (MTJ) devices, and more specifically, to fabrication methods and structures for MTJ devices having a divided tunnel barrier.

A magnetoresistive random-access memory (MRAM) device is a type of solid state, non-volatile memory which stores data in an electrically connected array of magnetoresistive memory elements, referred to as magnetic tunnel junctions (MTJs).

### SUMMARY

According to an embodiment of the present invention, a magnetic tunnel junction device is provided. The magnetic tunnel junction device includes a magnetic tunnel junction pillar formed above a bottom electrode. The magnetic tunnel junction pillar includes a reference layer formed above the bottom electrode, a free layer formed above the reference layer, and a tunnel barrier separating the reference layer from the free layer. The tunnel barrier includes a first tunnel barrier layer formed along top and sidewall surfaces of the reference layer, and a second tunnel barrier layer formed along bottom and sidewall surfaces of the free layer. The magnetic tunnel junction device further includes a top electrode formed above the magnetic tunnel junction pillar.

According to another embodiment of the present invention, a method of forming a magnetic tunnel junction device is provided. The method includes forming a magnetic tunnel junction pillar above a bottom electrode. Forming the magnetic tunnel junction pillar includes: forming a reference layer above the bottom electrode, forming a free layer above the reference layer, and forming a tunnel barrier that separates the reference layer from the free layer. Forming the tunnel barrier includes forming a first tunnel barrier layer on top and sidewall surfaces of the reference layer, and forming a second tunnel barrier layer on bottom and sidewall surfaces of the free layer. The method further includes forming a top electrode above the magnetic tunnel junction pillar.

### BRIEF DESCRIPTION OF THE SEVERAL VIEWS OF THE DRAWINGS

The drawings included in the present application are incorporated into, and form part of, the specification. They illustrate embodiments of the present invention and, along with the description, explain the principles of the invention. The drawings are only illustrative of certain embodiments and do not limit the invention.

FIG. 1 illustrates a cross-sectional view of a magnetic tunnel junction (MTJ) device 100 at an intermediate step during a semiconductor manufacturing process, in accordance with at least one embodiment of the present invention.

FIG. 2 illustrates a cross-sectional view of MTJ device 100 of FIG. 1 after performing subsequent processing steps, in accordance with at least one embodiment of the present invention.

FIG. 3 illustrates a cross-sectional view of MTJ device 100 of FIG. 2 after performing subsequent processing steps, in accordance with at least one embodiment of the present invention.

FIG. 4 illustrates a cross-sectional view of MTJ device 100 of FIG. 3 after performing subsequent processing steps, in accordance with at least one embodiment of the present invention.

FIG. 5 illustrates a cross-sectional view of MTJ device 100 of FIG. 4 after performing subsequent processing steps, in accordance with at least one embodiment of the present invention.

FIG. 6 illustrates a cross-sectional view of MTJ device 100 of FIG. 5 after performing subsequent processing steps, in accordance with at least one embodiment of the present invention.

FIG. 7 illustrates a cross-sectional view of MTJ device 100 of FIG. 6 after performing subsequent processing steps, in accordance with at least one embodiment of the present invention.

FIG. 8 illustrates a cross-sectional view of MTJ device 100 of FIG. 7 after performing subsequent processing steps, in accordance with at least one embodiment of the present invention.

FIG. 9 illustrates a cross-sectional view of MTJ device 100 of FIG. 8 after performing subsequent processing steps, in accordance with at least one embodiment of the present invention.

FIG. 10 illustrates a cross-sectional view of MTJ device 100 of FIG. 9 after performing subsequent processing steps, in accordance with at least one embodiment of the present invention.

FIG. 11 illustrates a cross-sectional view of MTJ device 100 of FIG. 10 after performing subsequent processing steps, in accordance with at least one embodiment of the present invention.

FIG. 12 illustrates a cross-sectional view of MTJ device 100 of FIG. 11 after performing subsequent processing steps, in accordance with at least one embodiment of the present invention.

FIG. 13 illustrates a cross-sectional view of MTJ device 100 of FIG. 12 after performing subsequent processing steps, in accordance with at least one embodiment of the present invention.

FIG. 14 illustrates a cross-sectional view of MTJ device 100 of FIG. 13 after performing subsequent processing steps, in accordance with at least one embodiment of the present invention.

FIG. 15 illustrates a cross-sectional view of MTJ device 100 of FIG. 14 after performing subsequent processing steps, in accordance with at least one embodiment of the present invention.

FIG. 16 illustrates a cross-sectional view of MTJ device 100 of FIG. 15 after performing subsequent processing steps, in accordance with at least one embodiment of the present invention.

FIG. 17 illustrates a cross-sectional view of MTJ device 100 of FIG. 16 after performing subsequent processing steps, in accordance with at least one embodiment of the present invention.

FIG. 18 illustrates a cross-sectional view of MTJ device 100 of FIG. 17 after performing subsequent processing steps, in accordance with at least one embodiment of the present invention.

FIG. 19 illustrates a cross-sectional view of MTJ device 100 of FIG. 18 after performing subsequent processing steps, in accordance with at least one embodiment of the present invention.

### DETAILED DESCRIPTION

The present invention generally relates to fabrication methods and structures for magnetic tunnel junction (MTJ) devices, and more specifically, to fabrication methods and structures for MTJ devices having a divided tunnel barrier.

An MTJ device, which is a primary storage element in a magnetoresistive random-access memory (MRAM), is a magnetic storage and switching device in which two ferromagnetic layers are separated by a thin non-magnetic insulating layer (i.e., a tunnel barrier) to form a stacked structure. One of the ferromagnetic layers of the MTJ device has a magnetization that is fixed, and it is therefore referred to as a magnetic fixed layer (or reference layer). The other ferromagnetic layer has a magnetization that can change, and it is therefore referred to as a magnetic free layer (or free layer). This configuration is known as a magnetic tunnel junction (MTJ) pillar. Conventional MTJ pillar structures may include a cobalt (Co)-based synthetic anti-ferromagnet (SAF), a CoFeB-based reference layer, a MgO-based tunnel barrier, a CoFeB-based free layer, and metal cap layers containing materials such as tantalum (Ta) and/or ruthenium (Ru).

For high performance MRAM devices based on perpendicular MTJ pillars, well-defined interfaces and interface control are essential. Typically, MTJ pillars are formed by subtractive patterning of blanket MTJ stacks in between two interconnect levels using, for example, reactive ion etching (RIE) or ion beam etching (IBE). After patterning the blanket MTJ stacks to form the MTJ pillars, the inter-pillar spaces are filled with an interlayer dielectric (ILD) to electrically isolate the MTJ pillars and to allow for the subsequent formation of electrical connections (e.g., top metal contacts) between the top electrode of the MTJ pillar and the various interconnect layers located above the MTJ device. However, due to the high aspect ratio of these inter-pillar spaces, this gap fill process typically results in the formation of voids in the ILD. This can ultimately lead to electrical shorts between neighboring MTJ pillars due to the filling of the voids in the ILD with a conductive metal material during the formation of the top metal contacts.

Embodiments of the present disclosure provide an MRAM device having a divided tunnel barrier structure, and a method of making the same, which improve upon the foregoing deficiencies of conventional MTJ pillar manufacturing. Rather than the conventional practice of patterning a blanket MTJ stack and subsequently filling the inter-pillar gaps with an ILD in a single gap fill step, embodiments of the present invention form an MTJ pillar and fill the inter-pillar gaps located between neighboring MTJ pillars in a stepwise manner.

According to embodiments of the present invention, metal caps are formed on top of lower electrically conductive structures (e.g., bottom metal contacts), followed by the deposition of a dielectric material on top thereof to form a first interlayer dielectric (ILD) layer. Bottom electrodes are then formed within the first ILD layer and above the metal contacts using, for example, a damascene process. Since the thickness of the first ILD layer need only match that of the desired thickness of the bottom electrodes, the risk of voids being formed in this ILD layer is significantly reduced and/or eliminated due to the low aspect ratio of the ILD layer.

After forming the bottom electrodes, a reference layer material is deposited and patterned to form a reference layer above the bottom electrodes using, for example, a subtractive manufacturing process. A tunnel barrier material is conformally deposited onto the top and sidewall surfaces of the patterned reference layer to form a first tunnel barrier layer, and the sidewall surfaces of the first tunnel barrier layer are covered by a dielectric encapsulation layer. It should be appreciated that at this stage in the manufacturing process, a thickness of the first tunnel barrier layer need only be roughly half of the overall required thickness of the tunnel barrier separating the reference layer from the free layer since a second tunnel barrier layer is formed at a later stage in the manufacturing process.

Next, a dielectric material is deposited to form a second interlayer dielectric (ILD) layer above the first tunnel barrier layer and within the inter-pillar gaps located between neighboring MTJ pillar structures. Since these inter-pillar gaps also have a low aspect ratio at this stage of the manufacturing process, the risk of voids being formed in the second ILD layer is again significantly reduced and/or eliminated due to the low aspect ratio of the ILD layer.

The second ILD layer is etched using one or more conventional patterning processes (e.g., lithography and etching) to form openings in the ILD layer above the reference layer, the openings are lined with a dielectric encapsulation layer, followed by an etch back of the dielectric encapsulation layer to expose the top surface of the first tunnel barrier layer. Another tunnel barrier material is then conformally deposited within the openings (i.e., along the top surface of the first tunnel barrier layer and along the dielectric encapsulation layer lining the sidewalls of the openings) to form a second tunnel barrier layer, and a free layer is formed within the openings lined with the second tunnel barrier layer. It should be appreciated that at this stage in the manufacturing process, a thickness of the second tunnel barrier layer need only be roughly half of the overall required thickness of the tunnel barrier separating the reference layer from the free layer since the first tunnel barrier layer was already formed at an earlier stage in the manufacturing process.

An additional third interlayer dielectric (ILD) layer may then be formed above the free layer and within the inter-pillar gaps located between neighboring MTJ pillar structures. Since these inter-pillar gaps also have a low aspect ratio at this stage in the manufacturing process, the risk of electrical shorts between neighboring MTJ devices caused by voids formed in the interlayer dielectric is once again significantly reduced and/or eliminated. Thereafter, upper electrically conductive structures (e.g., top metal contacts) are formed within the third ILD layer and above the free layer using, for example, a damascene process. It should be appreciated that due to the stepwise manner in which the MTJ device of the present invention is manufactured, the risk of electrical shorts between neighboring MTJ pillars is eliminated due to the void free dielectric gap fill process of the present invention.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this invention may be embodied in many different forms and should not be construed as limited to the exemplary embodiments set forth herein. Rather, these exemplary embodiments are provided so that this invention will be thorough and complete and will fully convey the scope of this invention to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” may mean that a first element can be etched, and the second element can act as an etch stop.

As used herein, terms such as “depositing,” “forming,” and the like may refer to the disposition of layers, or portions of materials, in accordance with a given embodiment. Such processes may or may not be different than those used in the standard practice of the art of semiconductor device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may also refer to processes that alter the structure and/or composition of one or more layers of material or portions of materials in accordance with a given embodiment. For example, such formation processes may include, but are not limited to, micromachining, microetching, wet and/or dry etching processes, plasma etching processes, or any of the known etching processes in which material is removed to form a particular structure.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

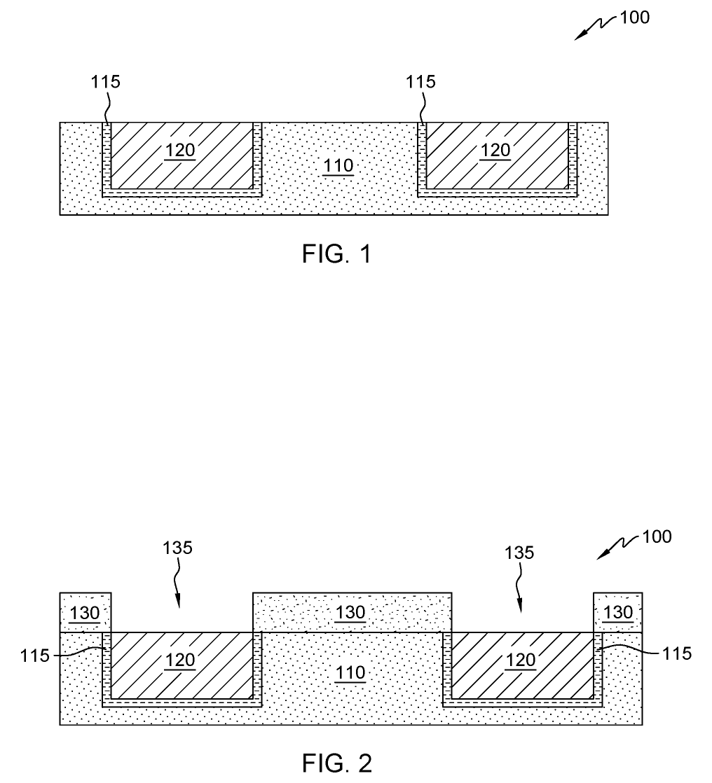

The present invention will now be described in detail with reference to the Figures, in which like numbers represent the same or similar elements. FIGS. 1-19 include various cross-sectional views depicting illustrative steps of methods for manufacturing MTJ devices and the resulting MTJ devices according to select embodiments of the present invention. One having ordinary skill in the art will appreciate that there are many options available for the formation of the structures described herein and that the following discussion does not limit embodiments to only the techniques described herein.

FIG. 1 depicts a cross-sectional view of a magnetic tunnel junction (MTJ) device 100 at an intermediate step during a semiconductor manufacturing process, in accordance with at least one embodiment of the present invention. The MTJ device 100 may be part of any MTJ-containing device, including, but not limited to, MRAM, spin-transfer torque (STT) MRAM, and spin-orbit torque (SOT) MRAM. In an embodiment, MTJ device 100 is an MRAM device based on a perpendicular MTJ pillar structure.

In assembly of MTJ device 100 of FIG. 1, lower electrically conductive structures 120 are formed within an interlayer dielectric (ILD) layer 110. Collectively, the lower electrically conductive structures 120 and the ILD layer 110 are part of an interconnect level. It should be noted that one or more additional back-end-of-the-line (BEOL) interconnect levels and/or middle-of-the-line (MOL) interconnect levels may be located beneath this interconnect level. These other levels are not shown for clarity. In some embodiments, the lower electrically conductive structures may be bottom metal contacts as understood by one of ordinary skill in the art.

The ILD layer 110 may be formed by depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The ILD layer 110 may be composed of an inorganic dielectric material or an organic dielectric material. Examples of suitable dielectric materials that may be employed as the ILD layer 110 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl. In some embodiments, the ILD layer 110 may have a dielectric constant (all dielectric constants mentioned herein are measured relative to a vacuum, unless otherwise stated) that is about 4.0 or less. In an embodiment, the ILD layer 110 may have a dielectric constant of 2.8 or less. Dielectric materials having a dielectric constant of 2.8 or less generally have a lower parasitic cross talk as compared to dielectric materials whose dielectric constant is greater than 4.0. In some embodiments, the ILD layer 110 may be porous. In other embodiments, the ILD layer 110 may be non-porous.

The lower electrically conductive structures 120 may be formed within the ILD layer 110 using one or more conventional BEOL semiconductor manufacturing processes (e.g., a damascene process or a dual damascene process) as known by one of ordinary skill in the art, and as such, a more detailed description of such processes is not presented herein. The lower electrically conductive structures 120 may be composed of a conductive material including, but not limited to, copper (Cu), aluminum (Al), ruthenium (Ru), rhodium (Rh), iridium (Ir), tantalum (Ta), tantalum nitride (TaN) titanium (Ti), titanium nitride (TiN), tungsten (W), molybdenum (Mo), nickel (Ni), or any combination thereof.

In some embodiments, and as depicted in FIG. 1, a diffusion barrier liner 115 is formed along the bottom and sidewall surfaces of openings (not depicted) formed within the ILD layer 110. The diffusion barrier liner 115 is composed of a diffusion barrier material (i.e., a material that serves as a barrier to prevent a conductive material used to form the lower electrically conductive structures 120 from diffusing into the ILD layer 110). The diffusion barrier liner 115 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

FIG. 2 illustrates a cross-sectional view of MTJ device 100 of FIG. 1 after performing subsequent processing steps, in accordance with at least one embodiment of the present invention. In assembly of MTJ device 100 of FIG. 2, a dielectric capping layer 130 is formed, followed by the patterning of the dielectric capping layer 130 to form openings 135 within the dielectric capping layer 130.

The dielectric capping layer 130 may be formed by depositing a dielectric capping material onto the ILD layer 110, diffusion barrier liner 115, and lower electrically conductive structures 120 using known deposition techniques, including, but not limited to, chemical vapor deposition (CVD), plasma enhanced chemical vapor deposition (PECVD), atomic layer deposition (ALD), physical vapor deposition (PVD), sputtering, chemical solution deposition, or plating. Suitable dielectric capping materials for the dielectric capping layer 130 may include, but are not limited to, silicon carbide (SiC), silicon nitride (SiN), a nitrogen and hydrogen doped silicon carbide (SiC(N,H)), or any combination thereof.

Following the formation of the dielectric capping layer 130, the dielectric capping layer 130 is etched using one or more conventional patterning processes (e.g., lithography and etching) to form openings 135 in the dielectric capping layer 130. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the dielectric capping layer 130, and the hard mask material is patterned to form a patterned hard mask (not depicted). Then, using the patterned hard mask, the dielectric capping layer 130 is etched (using, for example, reactive ion etching (RIE), ion beam etching (IBE), chemical wet etching, or a combination of IBE and chemical wet etching) to form the openings 135 within the dielectric capping layer 130. The etching of the dielectric capping layer 130 can be controlled by a timed etching process as known by one of ordinary skill in the art, such that the etching process is terminated upon reaching the top surface of the lower electrically conductive structures 120.

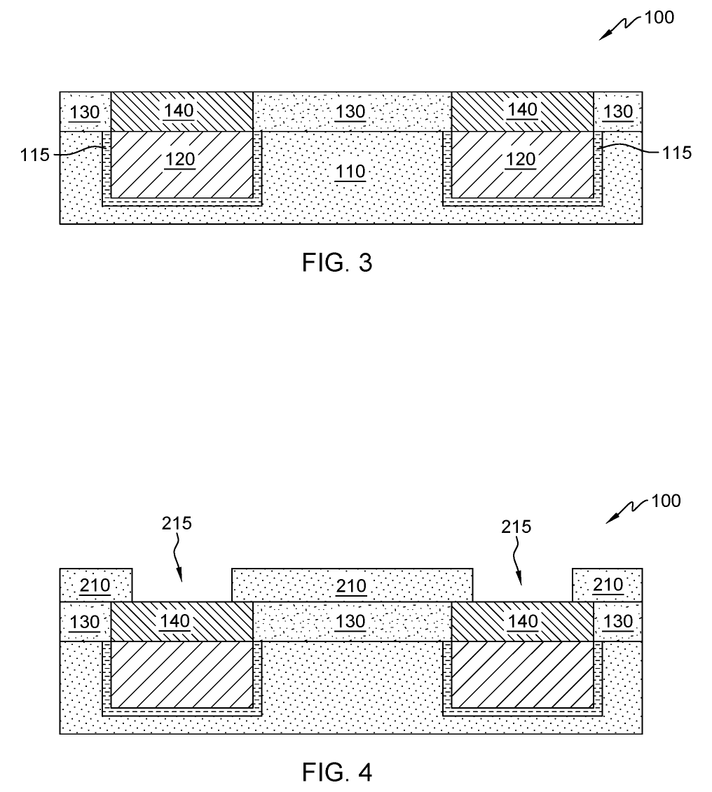

FIG. 3 illustrates a cross-sectional view of MTJ device 100 of FIG. 2 after performing subsequent processing steps, in accordance with at least one embodiment of the present invention. In assembly of MTJ device 100 of FIG. 3, metal caps 140 are formed on top of the lower electrically conductive structures 120.

The metal caps 140 may be formed by depositing a metal cap material onto the top surface of the dielectric capping layer 130, and on the bottom and sidewall surfaces of the openings 135 (depicted in FIG. 2) formed within the dielectric capping layer 130 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable metal cap materials for the metal caps 140 may include, but are not limited to, niobium (Nb), tungsten (W), tantalum (Ta), titanium (Ti), ruthenium (Ru), or any combination thereof.

Following the deposition of the metal cap material, a planarization process such as, for example, chemical mechanical planarization or polishing (CMP), and/or grinding, may subsequently be performed to remove portions of the metal cap material located above the top surface of the dielectric capping layer 130. The planarization stops at the top surface of the dielectric capping layer 130, such that the top surface of the metal caps 140 is substantially coplanar with the top surface of the dielectric capping layer 130.

FIG. 4 illustrates a cross-sectional view of MTJ device 300 of FIG. 3 after performing subsequent processing steps, in accordance with at least one embodiment of the present invention. In assembly of MTJ device 100 of FIG. 4, an interlayer dielectric (ILD) layer 210 is formed by depositing a dielectric material onto the dielectric capping layer 130 and metal caps 140, followed by the patterning of the ILD layer 210 to form openings 215 within the ILD layer 210.

The dielectric material of the ILD layer 210 may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition, and may include any of the dielectric materials previously described with respect to the ILD layer 110 of FIG. 1. As depicted by FIG. 4, the ILD layer 210 is composed of a dielectric material that is compositionally different than the dielectric material of the dielectric capping layer 130.

Following the deposition of the dielectric material, the ILD layer 210 is etched using one or more conventional patterning processes (e.g., lithography and etching) to form openings 215 in the ILD layer 210. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the ILD layer 210, and the hard mask material is patterned to form a patterned hard mask (not depicted). Then, using the patterned hard mask, the ILD layer 210 is etched (using, for example, reactive ion etching (RIE), ion beam etching (IBE), chemical wet etching, or a combination of IBE and chemical wet etching) to form the openings 215 within the ILD layer 210 that expose at least a portion of the top surface of the metal caps 140. The etching of the ILD layer 210 can be controlled by a timed etching process as known by one of ordinary skill in the art, such that the etching process is terminated upon reaching the top surface of the metal caps 140.

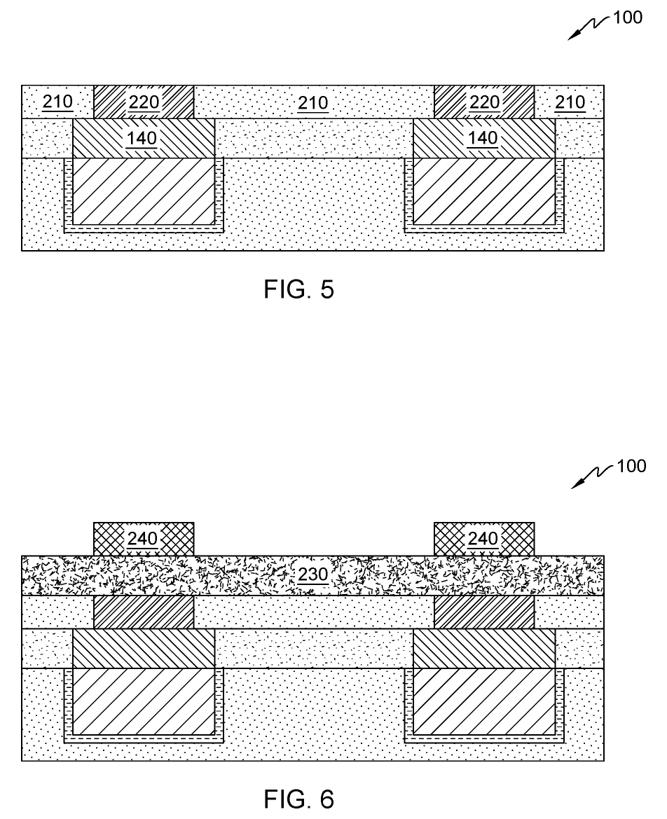

As depicted by FIG. 4, the ILD layer 210 layer has a low aspect ratio (i.e., the thickness or height of the dielectric material is low compared to the width of the dielectric material added). This stems from the fact that the thickness of the ILD layer 210, and thereby the depth of the openings 215 formed within the ILD layer 210, need only match a desired thickness of the bottom electrodes 220 (depicted in FIG. 5) formed within the openings 215. It should be appreciated that due to this low aspect ratio, the risk of voids being formed while depositing the dielectric material to form the ILD layer 210 is significantly reduced and/or eliminated.

FIG. 5 illustrates a cross-sectional view of MTJ device 100 of FIG. 4 after performing subsequent processing steps, in accordance with at least one embodiment of the present invention. In assembly of MTJ device 100 of FIG. 5, bottom electrodes 220 are formed on top of the metal caps 140.

The bottom electrodes 220 may be formed by depositing an electrode material onto the top surface of the ILD layer 210, and on the bottom and sidewall surfaces of the openings 215 (depicted in FIG. 4) formed within the ILD layer 210 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The bottom electrodes 220 may be composed of a conductive material including, but not limited to, copper (Cu), aluminum (Al), ruthenium (Ru), rhodium (Rh), iridium (Ir), tantalum (Ta), tantalum nitride (TaN), titanium (Ti), titanium nitride (TiN), tungsten (W), molybdenum (Mo), or any combination thereof.

Following the deposition of the electrode material, a planarization process such as, for example, chemical mechanical planarization or polishing (CMP), and/or grinding, may subsequently be performed to remove portions of the electrode material located above the top surface of the ILD layer 210. The planarization stops at the top surface of the ILD layer 210, such that the top surface of the bottom electrodes 220 is substantially coplanar with the top surface of the ILD layer 210.

FIG. 6 illustrates a cross-sectional view of MTJ device 500 of FIG. 5 after performing subsequent processing steps, in accordance with at least one embodiment of the present invention. In assembly of MTJ device 100 of FIG. 6, a reference layer 230 (i.e., a magnetic fixed layer or fixed layer) is formed, followed by the formation of a patterned hard mask 240 on top of the reference layer 230.

The reference layer 230 may be formed by depositing a reference layer material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The reference layer 230 has a fixed magnetization and includes a metal or metal alloy (or a stack thereof) that exhibits a high spin polarization. Suitable reference layer materials for the reference layer 230 may include, but are not limited to, metals such as iron (Fe) boron (B), platinum (Pt), nickel (Ni), tungsten (W), or iridium (Ir), metal alloys such as cobalt-iron (CoFe), cobalt-iron-nickel (CoFeNi), iron-boron (FeB), cobalt-iron-boron (CoFeB), or any combination thereof. In some embodiments, the reference layer 230 may be a multilayer arrangement having (i) a high spin polarization region formed from a metal or metal alloy mentioned above, and (ii) a strong perpendicular magnetic anisotropy (PMA) region formed from a metal or metal alloy that exhibits a strong PMA. Suitable metals that exhibit a strong PMA may include, but are not limited to, cobalt (Co), nickel (Ni), platinum (Pt), palladium (Pd), iridium (Ir), or Ruthenium (Ru), and may be arranged as alternating layers. Suitable metal alloys that exhibit a strong PMA may include, but are not limited to, cobalt-iron-terbium (CoFeTb), cobalt-iron-gadolinium (Co-Fe-Gd), cobalt-chromium-platinum (CoCrPt), cobalt-platinum (CoPt), cobalt-palladium (CoPd), iron-platinum (FePt), or iron-palladium (FePd), and may be arranged as alternating layers.

By way of example, the patterned hard mask 240 may be formed as follows. A hard mask material (e.g., silicon nitride, titanium nitride, tantalum nitride, or any suitable inorganic metal-containing material) is deposited onto the top surface of the reference layer 230, followed by the deposition of photoresist material (not depicted) on top thereof using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. A photomask (not depicted) patterned with shapes defining the patterned structure to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask material. Dry etch techniques (for example, an anisotropic etch process, such as reactive ion etch) may be employed to selectively remove portions of the hard mask material to form the patterned hard mask 240. After formation of the patterned hard mask 240, the photoresist material may be stripped from the patterned hard mask 240 by ashing or other suitable processes. The resulting structure may be subjected to a wet clean.

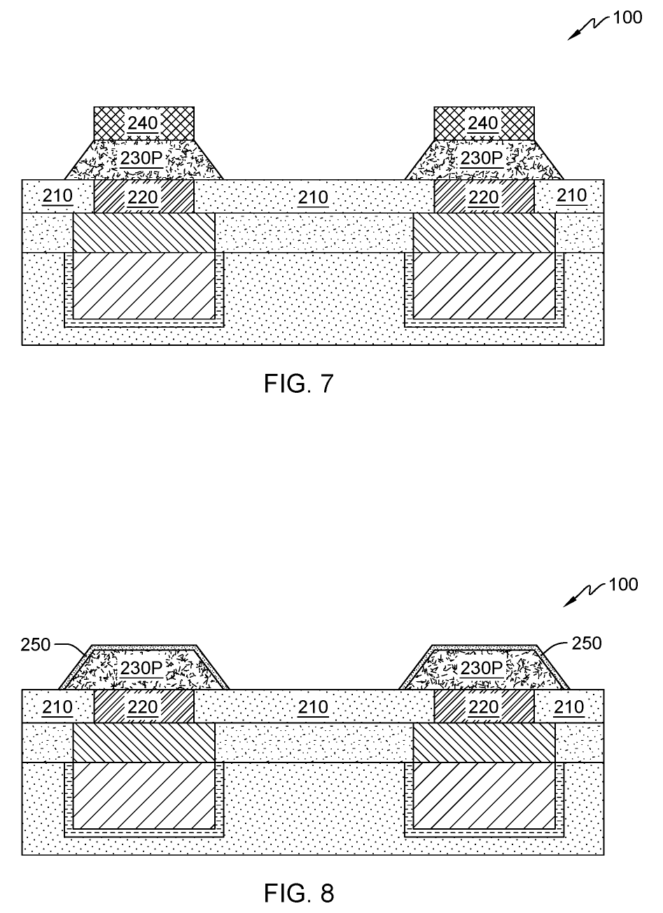

FIG. 7 illustrates a cross-sectional view of MTJ device 100 of FIG. 6 after performing subsequent processing steps, in accordance with at least one embodiment of the present invention. In assembly of MTJ device 100 of FIG. 7, the patterned hard mask 240 is used to pattern the reference layer 230 (depicted in FIG. 6). The resulting patterned reference layer 230 shall hereinafter be referred to as reference layer 230P.

During patterning of the reference layer 230 using the patterned hard mask 240, portions of the reference layer 230 are removed by a directional etching process (e.g., reactive ion etching (RIE), ion beam etching (IBE), or any combination thereof). The etching of the reference layer 230 can be controlled by a timed etching process as known by one of ordinary skill in the art, such that the etching process is terminated upon reaching the top surface of the ILD layer 210.

As depicted by FIG. 7, the reference layer 230P is located above the bottom electrodes 220 and has a tapered sidewall profile that gradually decreases in width moving from the bottom surface to the top surface of the reference layer 230P. In other words, the sidewalls of the reference layer 230P taper inwards towards the top surface. However, it should be appreciated that embodiments of the present invention are not limited to the tapered sidewall profile of the reference layer 230P as depicted in FIG. 7. For example, in some embodiments (not depicted), the reference layer 230P may have a tapered sidewall profile that gradually decreases in width moving from the top surface to the bottom surface of the reference layer 230P (i.e., the sidewalls taper inwards towards the bottom surface. In other embodiments (not depicted), the reference layer 230P may have a substantially vertical sidewall profile.

FIG. 8 illustrates a cross-sectional view of MTJ device 100 of FIG. 7 after performing subsequent processing steps, in accordance with at least one embodiment of the present invention. In assembly of MTJ device 100 of FIG. 8, the patterned hard mask 240 (depicted in FIG. 7) is removed, and a first tunnel barrier layer 250 is formed on the top and sidewall surfaces of the reference layer 230P.

After removal of the patterned hard mask 240 (depicted in FIG. 7) using one or more processes as known by one of ordinary skill in the art, the first tunnel barrier layer 250 may be formed, for example, by conformally depositing a tunnel barrier material that is selective to the material of the reference layer 230P over the material of the ILD layer 210 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable tunnel barrier materials used to form the first tunnel barrier layer 250 may include a non-magnetic insulator such as magnesium oxide (MgO), aluminum oxide (e.g., Al₂O₃), titanium oxide, gadolinium oxide, tantalum oxide, molybdenum oxide, tungsten oxide, or any combination thereof.

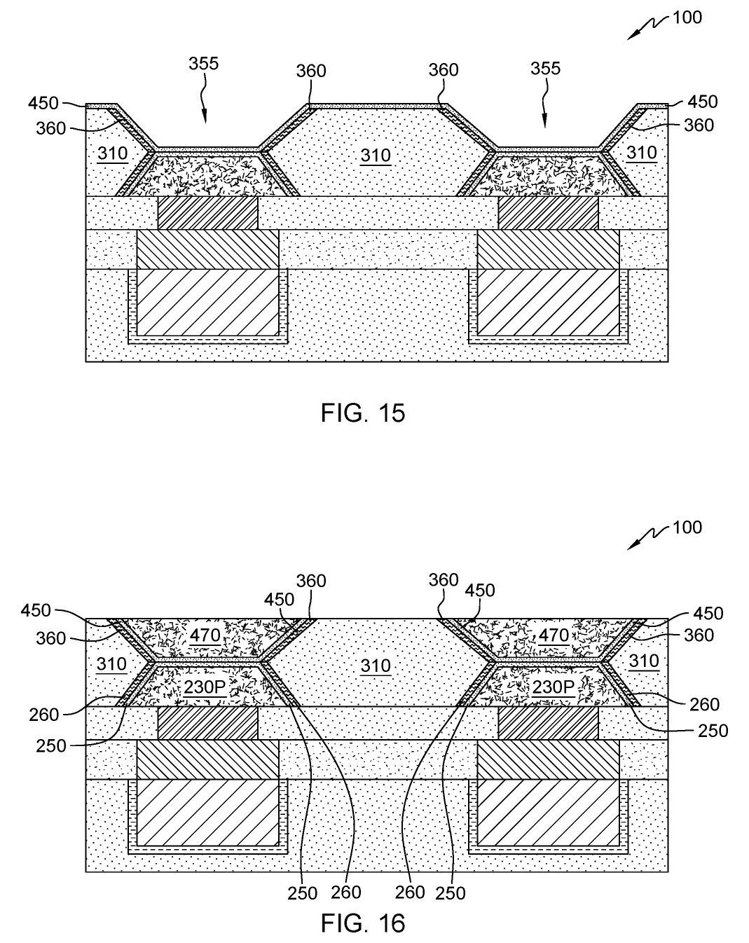

As depicted by FIG. 8, due to the tunnel barrier material being selective to the material of the reference layer 230P over the material of the ILD layer 210, the first tunnel barrier layer is only formed on the top and sidewall surfaces of the reference layer 230P. It should be appreciated that at this stage in the manufacturing process, a thickness of the first tunnel barrier layer need only be roughly half of the overall required thickness of the tunnel barrier separating the reference layer 230P from the free layer 470 (depicted in FIG. 16) since a second tunnel barrier layer 450 (depicted in FIG. 15) is formed at a later stage in the manufacturing process.

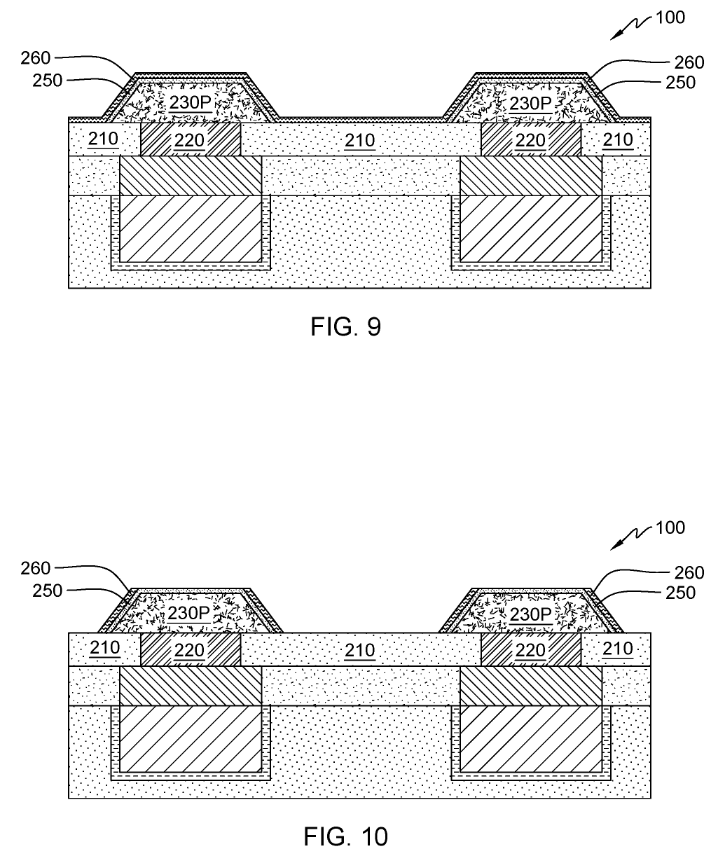

FIG. 9 illustrates a cross-sectional view of MTJ device 100 of FIG. 8 after performing subsequent processing steps, in accordance with at least one embodiment of the present invention. In assembly of MTJ device 100 of FIG. 9, a dielectric encapsulation layer 260 is formed onto the physically exposed surfaces of the ILD layer 210 and the first tunnel barrier layer 250.

The dielectric encapsulation layer 260 may be formed by conformally depositing a dielectric material onto the top surface of the ILD layer 210, and on the top and sidewall surfaces of the first tunnel barrier layer 250 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable dielectric materials used to form the dielectric encapsulation layer 260 may include, but are not limited to, silicon carbide (SiC), silicon nitride (SiN), silicon dioxide (SiO₂) aluminum oxide (Al₂O₃), amorphous carbon (a-C), silicon silicoboron carbonitride (SiOCN), silicon oxcycarbonitride (SiOCN), or any combination thereof.

FIG. 10 illustrates a cross-sectional view of MTJ device 100 of FIG. 9 after performing subsequent processing steps, in accordance with at least one embodiment of the present invention. In assembly of MTJ device 100 of FIG. 10, an etch back of the dielectric encapsulation layer 260 is performed, for example, using a directional anisotropic etching process as known by one of ordinary skill in the art. The etching process removes the respective portions of the dielectric encapsulation layer 260 formed on the top surfaces of the ILD layer 210 and first tunnel barrier layer 250, respectively. The etching of the dielectric encapsulation layer 260 can be controlled by a timed etching process as known by one of ordinary skill in the art, such that the etching process is terminated upon reaching the top surfaces of the ILD layer 210 and first tunnel barrier layer 250, respectively. As depicted by FIG. 10, after the etch back of the dielectric encapsulation layer 260, the sidewalls of the first tunnel barrier layer 250 remain covered by the dielectric encapsulation layer 260.

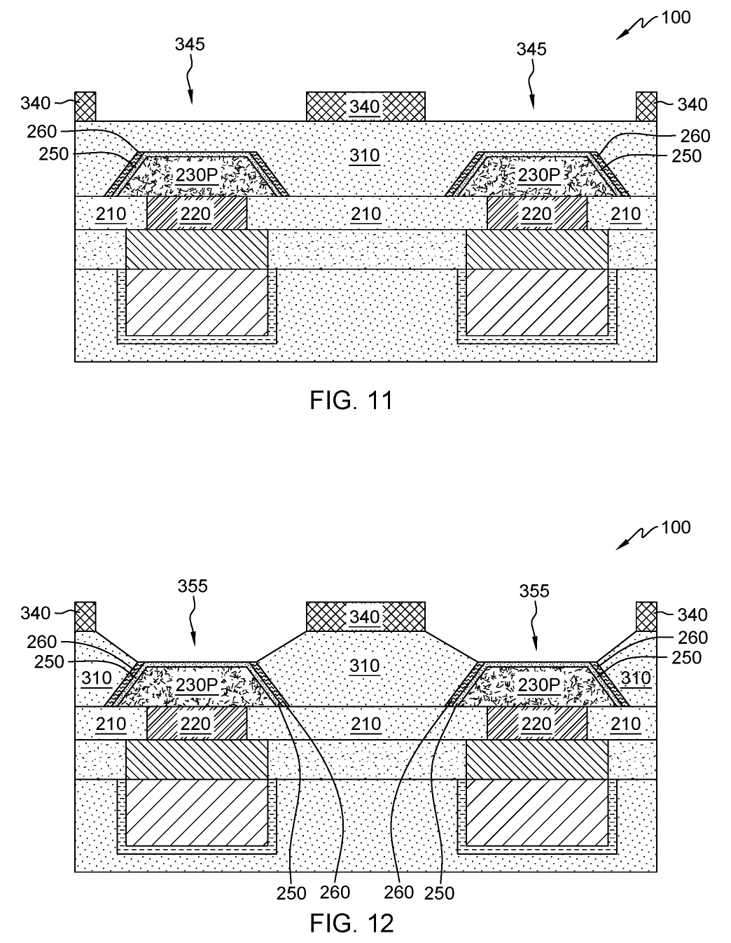

FIG. 11 illustrates a cross-sectional view of MTJ device 100 of FIG. 10 after performing subsequent processing steps, in accordance with at least one embodiment of the present invention. In assembly of MTJ device 100 of FIG. 11, an interlayer dielectric (ILD) layer 310 is formed by depositing a dielectric material onto the physically exposed surfaces of the ILD layer 210, first tunnel barrier layer 250 and dielectric encapsulation layer 260, and a hard mask material is deposited on top of the ILD layer 310 and patterned to form a patterned hard mask 340.

The respective dielectric and hard mask materials may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition, and may include any of the dielectric materials or hard mask materials previously described with respect to the ILD layer 110 of FIG. 1 and the patterned hard mask 240 of FIG. 6. Following the deposition of the dielectric material, a planarization process such as, for example, chemical mechanical planarization or polishing (CMP), and/or grinding, may subsequently be performed to create a substantially planar top surface. As depicted by FIG. 11, the ILD layer 310 is formed within the inter-pillar gaps located laterally adjacent to reference layer 230P and above the top surface of first tunnel barrier layer 250. This is to allow for the subsequent formation of openings 355 (depicted in FIG. 12) within the ILD layer 310 located above the reference layer 230P.

The hard mask material deposited on top of the ILD layer 310 may be patterned to form the patterned hard mask 340 using the same patterning process (e.g., lithography and etching) as previously described with respect to forming the patterned hard mask 240 of FIG. 6. The patterning of the hard mask material to form the patterned hard mask 340 further results in the formation of openings 345 that extend completely through the hard mask material, such that the openings 345 expose a portion of the top surface of the ILD layer 310 located above the reference layer 230P, first tunnel barrier layer 250, and dielectric encapsulation layer 260.

As depicted by FIG. 11, the ILD layer 310 layer has a low aspect ratio (i.e., the thickness or height of the dielectric material is low compared to the width of the dielectric material added). It should be appreciated that due to this low aspect ratio, the likelihood of voids being formed while depositing the dielectric material within the inter-pillar gaps located between neighboring MTJ devices at this stage in the semiconductor manufacturing process is significantly reduced and/or eliminated.

FIG. 12 illustrates a cross-sectional view of MTJ device 100 of FIG. 11 after performing subsequent processing steps, in accordance with at least one embodiment of the present invention. In assembly of MTJ device 100 of FIG. 12, the patterned hard mask 340 is used to form openings 355 in the ILD layer 310.

The openings 355 in the ILD layer 310 may be formed, for example, as follows. Using the patterned hard mask 340, which acts as an etch mask, the physically exposed portions of the ILD layer 310 located below the openings 345 (depicted in FIG. 11) in the patterned hard mask 340 are removed by a directional anisotropic etching process (e.g., reactive ion etching (RIE), ion beam etching (IBE), or any combination thereof) to form the openings 355 within the ILD layer 310. The etching of the ILD layer 310 can be controlled by a timed etching process as known by one of ordinary skill in the art, such that the etching process is terminated upon reaching the top surfaces of the first tunnel barrier layer 250 and the dielectric encapsulation layer 260, respectively.

As depicted by FIG. 12, the openings 345 expose the top surfaces of the first tunnel barrier layer 250 and the dielectric encapsulation layer 260, and have tapered sidewall profiles that gradually decrease in width moving from the top to the bottom of the openings 355. In other words, the sidewall profiles of the openings 355 formed within the ILD layer 310 gradually taper inwards toward the bottom of the openings 355.

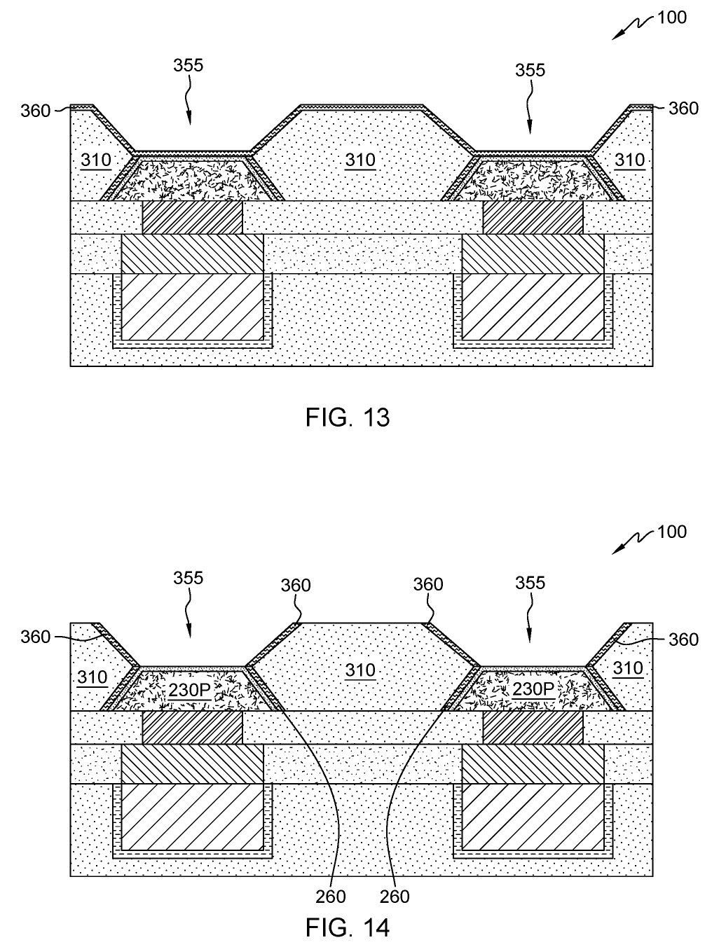

FIG. 13 illustrates a cross-sectional view of MTJ device 100 of FIG. 12 after performing subsequent processing steps, in accordance with at least one embodiment of the present invention. In assembly of MTJ device 100 of FIG. 12, the patterned hard mask 340 (depicted in FIG. 12) is removed and a dielectric encapsulation layer 360 is formed on the top surface of the ILD layer 310, and along the bottom and sidewall surfaces of the openings 355 in the ILD layer 310.

After removal of the patterned hard mask 340 (depicted in FIG. 12) using one or more processes as known by one of ordinary skill in the art, the dielectric encapsulation layer 360 may be formed by conformally depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable dielectric materials used to form the dielectric encapsulation layer 360 may include, but are not limited to, silicon carbide (SiC), silicon nitride (Si₃N₄), silicon dioxide (SiO₂) aluminum oxide (Al₂O₃), amorphous carbon (a-C), silicon silicoboron carbonitride (SiOCN), silicon oxcycarbonitride (SiOCN), or any combination thereof.

In some embodiments, and as depicted by FIG. 13, the dielectric encapsulation layer 360 is composed of a dielectric material that is compositionally similar to the dielectric material of the dielectric encapsulation layer 260. However, in other embodiments (not depicted), the dielectric encapsulation layer 360 may be composed of a dielectric material that is compositionally different than the dielectric material of the dielectric encapsulation layer 260.

FIG. 14 illustrates a cross-sectional view of MTJ device 100 of FIG. 13 after performing subsequent processing steps, in accordance with at least one embodiment of the present invention. In assembly of MTJ device 100 of FIG. 14, an etch back of the dielectric encapsulation layer 360 is performed, for example, using a directional anisotropic etching process as known by one of ordinary skill in the art. The etching process removes the respective portions of the dielectric encapsulation layer 360 formed above the top surfaces of the first tunnel barrier layer 250 and ILD layer 310, respectively. The etching of the dielectric encapsulation layer 360 can be controlled by a timed etching process as known by one of ordinary skill in the art, such that the etching process is terminated upon reaching the top surfaces of the first tunnel barrier layer 250 and ILD layer 310, respectively. After the etch back of the dielectric encapsulation layer 360, the sidewall surfaces of the openings 355 formed within the ILD layer 310 remain covered by the dielectric encapsulation layer 360, while the top surface of the first tunnel barrier layer 250 located above the reference layer 230P is left exposed.

FIG. 15 illustrates a cross-sectional view of MTJ device 100 of FIG. 14 after performing subsequent processing steps, in accordance with at least one embodiment of the present invention. In assembly of MTJ device 100 of FIG. 15, a second tunnel barrier layer 450 is formed onto the physically exposed surfaces of the first tunnel barrier layer 250, ILD layer 310, and dielectric encapsulation layer 360.

The second tunnel barrier layer 450 may be formed by conformally depositing a tunnel barrier material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable tunnel barrier materials used to form the second tunnel barrier layer 450 may include a non-magnetic insulator such as magnesium oxide (MgO), aluminum oxide (e.g., Al₂O₃), titanium oxide, gadolinium oxide, tantalum oxide, molybdenum oxide, tungsten oxide, or any combination thereof.

As depicted by FIG. 15, the second tunnel barrier layer 450 is formed on the top surface of the first tunnel barrier layer 250, the top surface of the ILD layer 310, and on the top and sidewall surfaces of the dielectric encapsulation layer 360 lining the sidewalls of the openings 355 in the ILD layer 310. It should be appreciated that a thickness of the second tunnel barrier layer 450 need only be roughly half of the overall required thickness of the tunnel barrier separating the reference layer 230P from the free layer 470 (depicted in FIG. 16) since the first tunnel barrier layer 250 was previously formed at an earlier stage in the manufacturing process.

In some embodiments, and as depicted by FIG. 15, the second tunnel barrier layer 450 is composed of a tunnel barrier material that is compositionally similar to the tunnel barrier material of the first tunnel barrier layer 250. However, in other embodiments (not depicted), the second tunnel barrier layer 450 may be composed of a tunnel barrier material that is compositionally different than the tunnel barrier material of the first tunnel barrier layer 250.

FIG. 16 illustrates a cross-sectional view of MTJ device 100 of FIG. 15 after performing subsequent processing steps, in accordance with at least one embodiment of the present invention. In assembly of MTJ device 100 of FIG. 16, a free layer 470 (i.e., magnetic free layer) is formed within the openings 355 (depicted in FIG. 15), followed by a planarization process.

The free layer 470 may be composed of a magnetic material (or stack of magnetic materials) having a magnetization that can be switched in orientation relative to the magnetization orientation of the reference layer 230P. The free layer 470 may be formed by depositing a free layer material within the openings 355 (depicted in FIG. 15) lined with the second tunnel barrier layer 450, using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable free layer materials used to form the free layer 470 may include, but are not limited to, metals such as cobalt (Co), Iron (Fe), Boron (B), or any combination thereof, and metal alloys such cobalt-iron (CoFe), iron-boron (FeB), cobalt-iron-boron (CoFeB), or any combination thereof.

Following the deposition of the free layer material, a planarization process such as, for example, chemical mechanical planarization or polishing (CMP), and/or grinding, may subsequently be performed to remove portions of the second tunnel barrier layer 450 and free layer 470 located above the top surface of the ILD layer 310. The planarization stops at the top surface of the ILD layer 310, such that the top surfaces of the dielectric encapsulation layer 360, second tunnel barrier layer 450, and free layer 470 are substantially coplanar with the top surface of the ILD layer 310.

As depicted by FIG. 16, the free layer 470 has a tapered sidewall profile that gradually decreases in width moving from the top surface to the bottom surface of the free layer 470. In other words, the sidewalls of the free layer 470 taper inward towards the bottom. However, it should be appreciated that embodiments of the present invention are not limited to the tapered sidewall profile of the free layer 470 as depicted in FIG. 16. For example, in some embodiments (not depicted), the free layer 470 may have a tapered sidewall profile that gradually decreases in width moving from the bottom surface to the top surface of the free layer 470 (i.e., the sidewalls taper inward towards the top). In other embodiments (not depicted), the free layer 470 may have a substantially vertical sidewall profile.

As further depicted by FIG. 16, the first tunnel barrier layer 250 covers the top and sidewall surfaces of the reference layer 230P, while the second tunnel barrier layer 450 covers the bottom and sidewall surfaces of the free layer 470. Additionally, since the first tunnel barrier layer 250 and the second tunnel barrier layer 450 are formed during two distinct steps in the manufacturing process, an interface is formed between the respective portions of the first and second tunnel barrier layers 250, 450 separating the reference layer 230P from the free layer 470.

Additionally, and as depicted by FIG. 16, a first thickness of the portion of the tunnel barrier located between the top surface of the reference layer 230P and the bottom surface of the free layer 470 (i.e., a combined thickness of the first tunnel barrier layer 250 formed above the top surface of the reference layer 230P and the second tunnel barrier layer 450 formed below the bottom surface of the free layer 470) is greater than a second thickness of the first and second tunnel barrier layers 250, 450 formed along the sidewall surfaces of the reference layer 230P and free layer 470, respectively. In some embodiments, the portion of the tunnel barrier separating the reference layer 230P from the free layer 470 has a thickness T, while the respective portions of the first and second tunnel barrier layers 250, 450 formed along the sidewalls of the reference layer 230P and free layer 470 have a thickness of ½ T. In an embodiment, T is greater than or equal to 0.5 nanometers and less than or equal to 1.0 nanometer. For example, if the combined thickness of the portion of the first and second tunnel barrier layers 250, 450 separating the reference layer 230P from the free layer 470 is 0.8 nanometers, then the thickness of the first and second tunnel barrier layers 250, 450 formed along the sidewalls of the reference layer 230P and free layer 470 would be 0.4 nanometers. However, other thicknesses and ratios of these tunnel barrier layers may be possible.

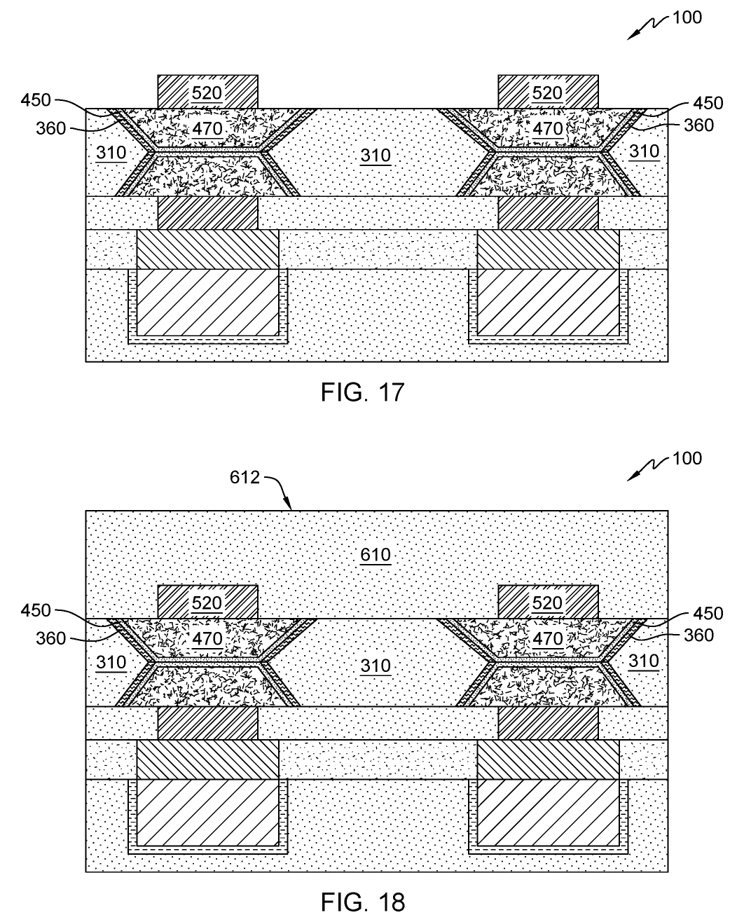

FIG. 17 illustrates a cross-sectional view of MTJ device 100 of FIG. 16 after performing subsequent processing steps, in accordance with at least one embodiment of the present invention. In assembly of MTJ device 100 of FIG. 17, top electrodes 520 are formed above the free layer 470.

The top electrodes 520 may be formed by depositing an electrode material onto the top surfaces of the ILD layer 310, dielectric encapsulation layer 360, second tunnel barrier layer 450, and free layer 470 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The top electrodes 520 may be composed of a conductive material including, but not limited to, copper (Cu), aluminum (Al), ruthenium (Ru), rhodium (Rh), iridium (Ir), tantalum (Ta), tantalum nitride (TaN), titanium (Ti), titanium nitride (TiN), tungsten (W), molybdenum (Mo), or any combination thereof.

The electrode material is then etched using one or more conventional patterning processes (e.g., lithography and etching) to form the top electrodes 520. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the electrode material, and the hard mask material is patterned to form a patterned hard mask (not depicted). Then, using the patterned hard mask, the electrode material is etched (using, for example, reactive ion etching (RIE), ion beam etching (IBE), chemical wet etching, or any combination thereof) to form the bottom electrodes 520.

In some embodiments, and as depicted by FIG. 16, the bottom electrodes 220 and the top electrodes 520 are composed of compositionally similar materials. However, in other embodiments (not depicted), the bottom electrodes 220 and the top electrodes 520 are composed of compositionally different materials.

FIG. 18 illustrates a cross-sectional view of MTJ device 100 of FIG. 17 after performing subsequent processing steps, in accordance with at least one embodiment of the present invention. In assembly of MTJ device 100 of FIG. 18, an interlayer dielectric (ILD) layer 610 is formed by depositing a dielectric material onto the physically exposed surfaces of the ILD layer 310, dielectric encapsulation layer 360, second tunnel barrier layer 450, free layer 470, and top electrodes 520, followed by a planarization process.

The dielectric material of the ILD layer 310 may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition, and may include any of the dielectric materials previously described with respect to the ILD layer 110 of FIG. 1. Following the deposition of the dielectric material, a planarization process such as, for example, chemical mechanical planarization or polishing (CMP), and/or grinding, may subsequently be performed to create a substantially planar top surface 612.

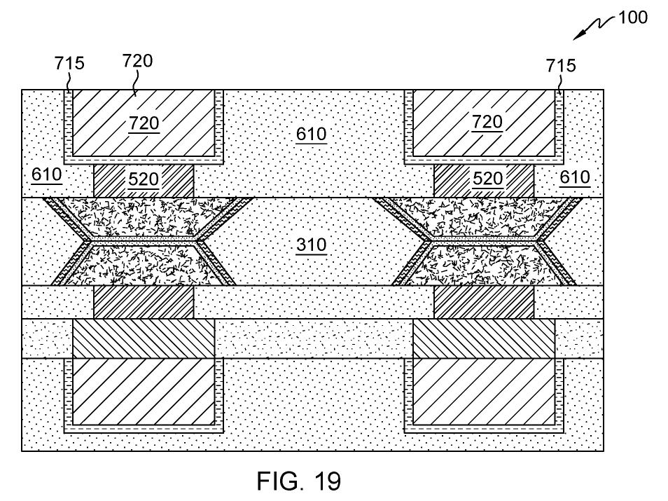

As depicted by FIG. 18, the ILD layer 610 is formed such that the top surface 612 of the ILD layer 610 is located laterally adjacent to and above the top electrodes 520. This is to allow for the subsequent formation of upper electrically conductive structures 720 (depicted in FIG. 19) within the ILD layer 610 located above the top electrodes 620.

As further depicted by FIG. 18, the ILD layer 610 has a low aspect ratio (i.e., the thickness or height of the dielectric material is low compared to the width of the dielectric material added). It should be appreciated that due to this low aspect ratio, the likelihood of voids being formed while depositing the dielectric material in the inter-pillar gaps between neighboring MTJ devices at this stage in the semiconductor manufacturing process is also significantly reduced and/or eliminated.

FIG. 19 illustrates a cross-sectional view of MTJ device 100 of FIG. 19 after performing subsequent processing steps, in accordance with at least one embodiment of the present invention. In assembly of MTJ device 100 of FIG. 19, upper electrically conductive structures 720 are formed within the ILD layer 610 located above the top electrodes 620. Collectively, the upper electrically conductive structures 720 and the ILD layer 610 are part of an interconnect level. It should be noted that one or more additional BEOL interconnect levels and/or MOL interconnect levels may be located above this interconnect level. These other levels are not shown for clarity. In some embodiments, the upper electrically conductive structures 720 may be top metal contacts as understood by one of ordinary skill in the art.

The upper electrically conductive structures 720 may be formed within the ILD layer 610 using one or more conventional BEOL semiconductor manufacturing processes (e.g., a damascene process or a dual damascene process) as known by one of ordinary skill in the art, and as such, a more detailed description of such processes is not presented herein. The upper electrically conductive structures 720 may be composed of a conductive material including, but not limited to, copper (Cu), aluminum (Al), ruthenium (Ru), rhodium (Rh), iridium (Ir), tantalum (Ta), tantalum nitride (TaN), titanium (Ti), titanium nitride (TiN), tungsten (W), molybdenum (Mo), or any combination thereof. In some embodiments, and as depicted in FIG. 19, the upper electrically conductive structures 720 and the lower electrically conductive structures 120 and are formed from compositionally similar materials. However, in other embodiments (not depicted), the upper electrically conductive structures 720 and the lower electrically conductive structures 220 may be formed from compositionally different materials.

In some embodiments, and as depicted in FIG. 19, a diffusion barrier liner 715 is formed along the bottom and sidewall surfaces of openings (not depicted) formed within the ILD layer 610 prior to depositing the conductive metal material to form the upper electrically conductive structures 720. The diffusion barrier liner 715 is composed of a diffusion barrier material (i.e., a material that serves as a barrier to prevent a conductive material used to form upper electrically conductive structures 720 from diffusing into the ILD layer 610). The diffusion barrier liner 715 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A magnetic tunnel junction device, comprising:
a bottom electrode;
a magnetic tunnel junction pillar formed above the bottom electrode, wherein the magnetic tunnel junction pillar includes:
a reference layer formed above the bottom electrode,
a free layer formed above the reference layer, and
a tunnel barrier separating the reference layer from the free layer, wherein the tunnel barrier includes:
a first tunnel barrier layer formed along top and sidewall surfaces of the reference layer, and
a second tunnel barrier layer formed along bottom and sidewall surfaces of the free layer; and
a top electrode formed above the magnetic tunnel junction pillar.

2. The magnetic tunnel junction device of claim 1, wherein a thickness of a first portion of the tunnel barrier located between the top surface of the reference layer and the bottom surface of the free layer is greater than a thickness of a second portion of the tunnel barrier formed along the sidewall surfaces of the reference layer and free layer.

3. The magnetic tunnel junction device of claim 1, wherein a first portion of the tunnel barrier located between the top surface of the reference layer and the bottom surface of the free layer has a thickness T and a second portion of the tunnel barrier formed along sidewall surfaces of the reference layer and free layer has a thickness ½ T.

4. The magnetic tunnel junction device of claim 3, wherein the thickness T is greater than or equal to 0.5 nanometers and less than or equal to 1.0 nanometer.

5. The magnetic tunnel junction device of claim 1, wherein the first tunnel barrier layer and the second tunnel barrier layer are formed from compositionally similar non-magnetic insulator materials.

6. The magnetic tunnel junction device of claim 1, wherein the first tunnel barrier layer and the second tunnel barrier layer are formed from compositionally different non-magnetic insulator materials.

7. The magnetic tunnel junction device of claim 1, wherein the reference layer is formed from a subtractive manufacturing process, and the free layer is formed from an additive manufacturing process.

8. The magnetic tunnel junction device of claim 1, further comprising:
a first dielectric encapsulation layer covering sidewall surfaces of the first tunnel barrier layer; and
a second dielectric encapsulation layer covering sidewall surfaces of the second tunnel barrier layer.

9. The magnetic tunnel junction device of claim 8, wherein first dielectric encapsulation layer and the second dielectric encapsulation layer are formed from compositionally similar dielectric materials.

10. The magnetic tunnel junction device of claim 8, wherein first dielectric encapsulation layer and the second dielectric encapsulation layer are formed from compositionally different dielectric materials.

11. The magnetic tunnel junction device of claim 1, wherein:
the reference layer has a tapered sidewall profile that gradually tapers inwards towards a top surface of the reference layer; and
the free layer has a tapered sidewall profile that gradually tapers inwards towards the bottom surface of the free layer.

12. The magnetic tunnel junction device of claim 1, wherein:
the reference layer has a tapered sidewall profile that gradually tapers inwards towards a bottom surface of the reference layer; and
the free layer has a tapered sidewall profile that gradually tapers inwards towards the top surface of the free layer.

13. The magnetic tunnel junction device of claim 1, wherein the reference layer and free layer have substantially vertical sidewall profiles.

14. A method of forming a magnetic tunnel junction device, comprising:
forming a bottom electrode;
forming a magnetic tunnel junction pillar above the bottom electrode, wherein forming the magnetic tunnel junction pillar includes:
forming a reference layer above the bottom electrode,
forming a free layer above the reference layer, and
forming a tunnel barrier separating the reference layer from the free layer, wherein forming the tunnel barrier includes forming a first tunnel barrier layer on top and sidewall surfaces of the reference layer, and forming a second tunnel barrier layer on bottom and sidewall surfaces of the free layer; and
forming a top electrode above the magnetic tunnel junction pillar.

15. The method of claim 14, wherein forming the first tunnel barrier layer includes conformally depositing a tunnel barrier material that is selective to a material used to form the reference layer.

16. The method of claim 14, further comprising forming a first dielectric encapsulation layer that covers sidewall surfaces of the first tunnel barrier layer.

17. The method of claim 14, wherein forming the second tunnel barrier layer includes:
forming an interlayer dielectric layer within inter-pillar gaps located laterally adjacent to reference layer and above the first tunnel barrier layer;
forming an opening in the interlayer dielectric layer above the reference layer, wherein the opening exposes the top surface of the first tunnel barrier layer;
forming a dielectric encapsulation layer that covers sidewall surfaces of the opening; and
conformally depositing a tunnel barrier material on the top surface of the first tunnel barrier layer and on sidewall surfaces of the dielectric encapsulation layer.

18. The method of claim 17, wherein forming the free layer includes depositing a free layer material on the second tunnel barrier layer and within the opening formed within the interlayer dielectric layer.

19. The method of claim 14, further comprising forming an electrically conductive structure above the top electrode.

20. The method of claim 19, wherein forming the electrically conductive structure includes:
forming an interlayer dielectric layer located laterally adjacent to and above the top electrode;
forming an opening in the interlayer dielectric layer above the top electrode, wherein the opening exposes the top surface of the top electrode;
conformally depositing a diffusion barrier liner material onto the bottom and sidewall surfaces of the opening; and
depositing a conductive material on top of the diffusion barrier liner material and within the opening.
